(19) United States
(12) Patent Application Publication
(10) Pub. No.: US 2004/0182603 A1
(43) Pub. Date: Sep. 23, 2004

(54) [INNER LAYER STRUCTURE OF A CIRCUIT BOARD]

(76) Inventors: Tz-Jang Tseng, Hsinchu (TW); Tsung-Chin Chiu, Taoyuan Hsien (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/604,474

(22) Filed: Jul. 24, 2003

(30) Foreign Application Priority Data
Mar. 21, 2003 (TW) 92204427

(51) Int. Cl. H05K 1/11

(52) U.S. Cl. 174/262; 174/264; 174/266; 174/267

(57) ABSTRACT

The present invention provides an inner layer structure of a circuit board. The inner layer structure of the present invention uses column-shaped or conned-shaped bumps to replace the conventional PTH process, and uses the bumps as media to electrically connect two adjacent patterned conducting layers. Hence, inner layer structure of the present invention can effectively simplify the layout design and the fabrication complexity, and increase the layout density of the circuit board.

### CROSS REFERENCE TO RELATED APPLICATIONS

This application claims the priority benefit of Taiwan application serial no. 92204427, filed Mar. 21, 2003.

### BACKGROUND OF INVENTION

1. Field of the Invention

This invention generally relates to an inner layer structure of a circuit board, and more particularly to an inner layer structure of a circuit board using bumps instead of conventional plated through holes (“PTH”) to electrically connect two patterned circuit layers.

2. Description of the Related Art

As the technology advances, new electronic products become more and more compact. Every electronic product at least has a mainboard consisting of electronic devices and circuit boards to electrically connect those devices. The most common circuit board is the printed circuit board (“PCB”).

FIGS. 1A-1F are the cross-sectional views of a four-conducting-layer PCB. Referring to FIG. 1A, a two-side board includes a dielectric core layer 110, conducting layers 120a and 120b, wherein conducting layers 120a and 120b are copper layers and are set on the two sides of the dielectric core layer 110 respectively. Referring to FIG. 1B, a plurality of through holes 112 are formed by using mechanical drill or laser drill technology to drill through the dielectric core layer 110 and the conducting layers 120a and 120b. Referring to FIG. 1C, the conducting layers 114a and 114b are formed by plating conducting materials on the surfaces of the conducting layers 120a and 120b. Furthermore, a plurality of conducting layers 114c are also formed on the inner side walls of the through holes 112 when conducting materials are plated. It should be noted that the conducting layers 120a and 114a are deemed a single conducting layer 122a and that the conducting layers 120b and 114b are deemed a single conducting layer 122b.

Referring to FIG. 1D, the dielectric materials 116 are filled into the through holes 112 to avoid voids in the through holes 112. Referring to FIG. 1E, the conducting lines and bonding pads are formed by patterning the conducting layers 122a and 122b via photolithography and etching processes. Referring to FIG. 1F, a four-conducting-layer PCB is formed by depositing the dielectric layers 130a and 130b and the conducting layers 140a and 140b and then laminating those layers.

The conventional lamination process of fabricating PCB has to use PTH process to electrically connect the patterned conducting layers. However, because the plating through holes occupy a certain area of the board, the layout density would be reduced.

### SUMMARY OF INVENTION

An object of the present invention is to provide an inner layer structure of a circuit board having bumps instead of conventional plated through holes to electrically connect two patterned circuit layers.

In accordance with the above object and other advantages of the present invention, an inner layer structure of a circuit board is provided. The inner layer structure of a circuit board comprises: a dielectric layer having a first side and a second side; a first bonding pad on the first side of the dielectric layer; a first bump, wherein the one end of the first bump is connected to the first bonding pad; a second bonding pad on the second side of the dielectric layer; and a second bump, wherein the one end of the second bump is connected to the second bonding pad.

The present invention also provides an inner layer structure of a circuit board, comprising: a dielectric layer having a first side and a second side, wherein the dielectric layer includes a through hole penetrating through the dielectric layer and the through hole connects the first side and the second side of the dielectric layer; a conducting plug within the through hole; and a bump, wherein the one end of the bump is connected to the end near the first side of the conducting plug.

The present invention further provides an inner layer structure of a circuit board, comprising: a dielectric layer having a first side and a second side, wherein the dielectric layer includes a through hole penetratingthrough the dielectric layer and the through hole connects the first side and the second side of the dielectric layer; a conducting plug within the through hole; a second dielectric layer having a third side; a bonding pad on the third side of the second dielectric layer; and a bump, wherein the one end of the bump is connected to the bonding pad and the other end of the bump is connected to the end of the conducting plug near the second side of the first dielectric layer.

The present invention still further provides an inner layer structure of a circuit board, comprising: a first dielectric layer having a first side; a first bonding pad on the first side of the first dielectric layer; a first bump, wherein the one end of the first bump is connected to the first bonding pad; a second dielectric layer having a second side; and a second bonding pad on the second side of the second dielectric layer, wherein the second bonding pad is connected to the other end of the first bump.

The inner layer structure of a circuit board of the present invention uses column-shaped or conned-shaped bumps to replace the conventional PTH process, and uses the bumps as media to electrically connect two adjacent patterned conducting layers.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF DRAWINGS

FIGS. 1A-1F are the cross-sectional views of a four-conducting-layer PCB.

FIG. 2 is the cross-sectional view of an inner layer structure before lamination in accordance with a preferred embodiment of the present invention.

FIG. 3 is the cross-sectional view of an inner layer structure after lamination in accordance with a preferred embodiment of the present invention.

FIG. 4 is the cross-sectional view of parts A and C in FIG. 3 in accordance with a preferred embodiment of the present invention.

FIG. 5 is a view of the inner layer structure including two bumps as media to transmit signals in accordance with a preferred embodiment of the present invention.

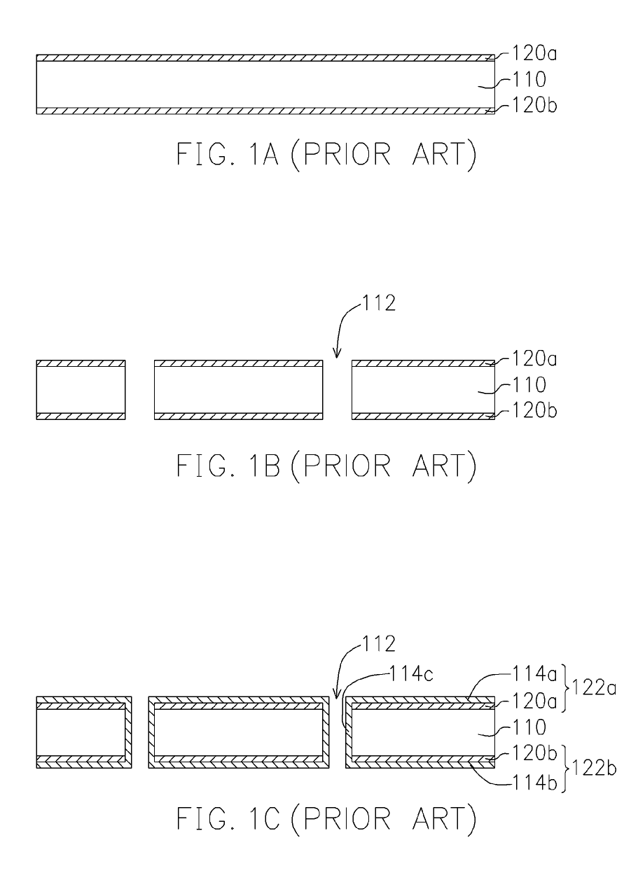

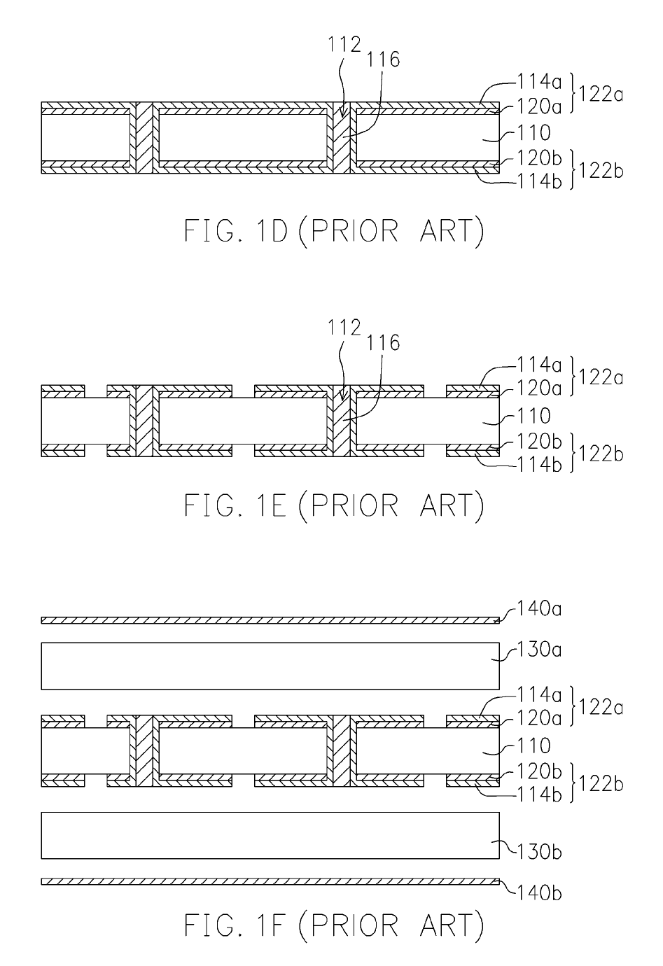

### DETAILED DESCRIPTION

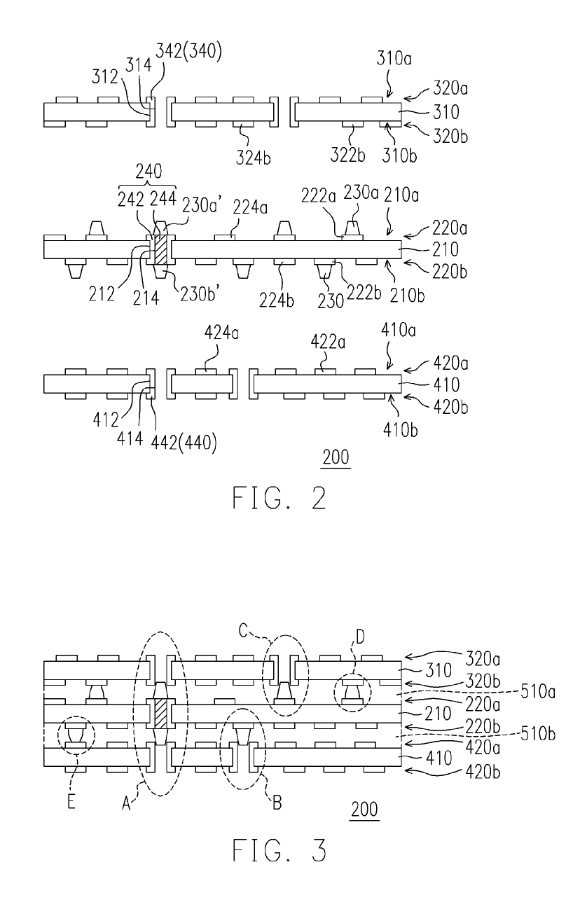

FIG. 2 is the cross-sectional view of an inner layer structure before lamination in accordance with a preferred embodiment of the present invention. The inner layer structure 200 includes a dielectric layer 210, a plurality of bonding pads 222a and 222b, and a plurality of bumps 230a and 230b, wherein the dielectric layer has a top side 210a and a bottom side 210b. The bonding pads 220a and 220b and bumps 230a and 230b are set on the top side 210a of the dielectric layer 210. One end of bump 230a is connected to the bonding pad 222a, wherein the bonding pad 222a is formed by the patterned circuit 220a and the patterned circuit 220a also forms the conducting line 224a. Furthermore, the bonding pad 222b is set on the bottom side 210b of the dielectric layer 210; one end of the bump 230b is connected to the bonding pad222b. Similarly, the bonding pad 222b is formed by the patterned circuit 220b and the patterned circuit 220b also forms the conducting line 224b.

Referring to FIG. 2, the inner layer structure 200 further comprises a conducting plug 240 within the through hole 212. When the conducting plug 240 is a PTH, the conducting plug 240 includes a conducting wall 242 and a dielectric column 244, wherein the conducting wall 242 is set on the side wall of the through hole 212, and a portion of the conducting wall 242 extending to the top side 210a of the dielectric layer 210 forms a ring pad. One end of the bump 230a″ is electrically and mechanically connected to the ring pad. Similarly, a portion of the conducting wall 242 extending to the bottom side 210b of the dielectric layer 210 forms a ring pad. The one end of the bump 230b″ is electrically and mechanically connected to the ring pad. Furthermore, the inner side of the conducting wall 242 forms a through hole 214; the dielectric material is filled with the through hole 214 to form the dielectric column. Because the one end of the bumps 230a and 230b can be connected to the ring pads of the conducting wall 242, the bumps 230a″ and 230b″ can be electrically connected via the conducting wall 242. One skilled in the art can easily understand that the conducting plug is not limited to PTH; e.g., the conducting plug can be a conducting column and the bump can be connected to the conducting column by connecting one end of the bump to one end of the conducting column.

Referring to FIG. 2, the inner layer structure 200 further comprises two double-side boards set above and below the dielectric layer 210 respectively. The top side 310a and bottom side 310b of the dielectric layer 310 have patterned circuits 320a and 320b respectively. The patterned circuit 320b further includes a bonding pad 322b and the conducting line 324b, wherein the position of the bonding pad 322b is corresponding to that of the bump 230a. The dielectric layer 310 further includes a through hole 312 through the dielectric layer 310 to connect the top side 310a and bottom side 310b. Furthermore, the conducting plug 340 is the conducting wall 342 that is set on the inner side wall of the through hole 306. The inner side of the conducting wall 342, which surrounds a through hole 314, is positioned corresponding to that of the bump 230a″.

Referring to FIG. 2, the top side 410a and bottom side 410b of the dielectric layer 410 have patterned circuits 420a and 420b respectively. The patterned circuit 420b further includes a bonding pad 422b and the conducting line 424b, wherein the position of the bonding pad 422b is corresponding to that of the bump 230b. The dielectric layer 310 further includes a through hole 412 through the dielectric layer 310 to connect the top side 410a and bottom side 410b. Furthermore, the conducting plug 440 is the conducting wall 442 that is set on the inner side wall of the through hole 406. The inner side of the conducting wall 442, which surrounds a through hole 414, is positioned corresponding to that of the bump 230b′.

FIG. 3 is the cross-sectional view of an inner layer structure (as shown in FIG. 2) after lamination in accordance with a preferred embodiment of the present invention. In this embodiment, a six-layer board is used as an example. Hence there is an additional dielectric layer 510a between the patterned circuits 320b and 220a; there is an additional dielectric layer 510b between the patterned circuits 220b and 420a. After laminating those material layers, the bumps of the bonding pads of the patterned circuit will connect to the bonding pads of the other patterned circuit; i.e., the bottom end of the bump is connected to the bonding pad, and the top end of the bump is connected to the other bonding pad.

Referring to FIGS. 2 and 3, for example, the bump 230a on the bonding pad 222a of the patterned circuit 220a is connected to the bonding pad 322b of the patterned circuit 320b; the bottom end of the bump 230a is connected to the bonding pad 222a, and the top end of the bump 230a is connected to the other bonding pad 322b. Furthermore, for the through hole 314 enclosed by the bump 230a′ and the conducting wall 342, because the outer diameter of the top end of the bump 230a′ is smaller than the inner diameter of the through hole 314, the top end of the bump 230a′ can be embedded in the through hole 314 and is connected to the inner side of the bottom side 310b of the conducting wall 342. Hence, the patterned circuit 320a is electrically connected to the patterned circuit 320b via the conducting wall 342 and then is electrically connected to the patterned circuit 220a via the bump 230a′.

Referring to FIG. 3, Part A shows that six patterned circuits 320a, 320b, 220a, 220b, 420a and 420b are electrically connected together via the bumps and the conducting wall of the conducting plug. Part B shows that three patterned circuits 220b, 420a and 420b are electrically connected together via the bumps and the conducting wall of the conducting plug. Part C shows that three patterned circuits 320a, 320b and 220a are electrically connected together via the bumps and the conducting wall of the conducting plug. Part D shows that two patterned circuits 320b and 220a are electrically connected together via the bumps. Part E shows that two patterned circuits 220b and 420a are electrically connected together via the bumps. Hence, the inner layer structure 200 of present invention use the bumps or the bumps and the conducting wall of the conducting plug to electrically connect two or more than two patterned circuits.

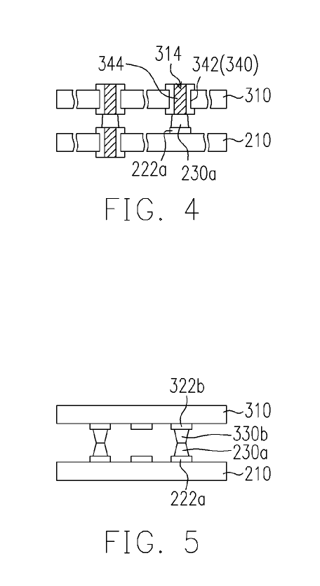

FIG. 4 is the cross-sectional view of Parts A and C in FIG. 3 in accordance with a preferred embodiment of the present invention. Taking Part C in FIG. 3 as an example, the outer diameter of the top end of the bump 230a can be larger than the inner diameter of the through hoe 314 so that the top end of the bump 230a would not be embedded in the through hole 314 but would be connected to the ring pad formed by the conducting wall 342 of the conducting plug 342, wherein the through hole is filled with the material 344 (e.g., conducting material or dielectric material.) FIG. 5 is the inner layer structure including two bumps as media to transmit signals in accordance with a preferred embodiment of the present invention. In some situations, e.g., when the distance between the dielectric layers 210 and 310 is not limited, or the bump 230a is not high enough, two bumps (e.g., bumps 230a and 330b) may be used as media to transmit signals. As shown in FIG. 5, the top end of the bump 330a is connected to the bonding pad 322b so that the bonding pad 322b is indirectly connected to the top end of the bump 230a via the bump 330b in order to electrically connect to the bonding pad 222a.

Accordingly, column-shaped or conned-shaped bumps may be used to replace the conventional PTH process, and these bumps may be used as media to electrically connect two adjacent patterned conducting layers. The present invention has the following advantages.

1. Because the bumps can electrically connect two adjacent patterned conducting layers as desired, and therefore the conventional PTH process is not required. Accordingly the inner layer structure the present invention can effectively simplify the layout of the PCB.

2. Because the sizes of the bumps are much smaller than the conducting plugs, and therefore the layout density can be effective increased by using bumps as media to connect patterned conducting layers.

3. When using bumps to replace the conventional PTH process, it only requires a single lamination step to achieve the electrical connection between patterned conducting layers. Hence, the inner layer structure of the present invention is capable of effectively simplifying the fabrication of the PCB.

The above description provides a full and complete description of the preferred embodiments of the present invention. Various modifications, alternate construction, and equivalent may be made by those skilled in the art without changing the scope or spirit of the invention. Accordingly, the above description and illustrations should not be construed as limiting the scope of the invention which is defined by the following claims.

1. An inner layer structure of a circuit board, comprising:
a dielectric layer having a first side and a second side;
a first bonding pad on said first side of said dielectric layer;
a first bump, wherein one end of said first bump is connected to said first bonding pad;
a second bonding pad on said second side of said dielectric layer; and
a second bump, wherein one end of said second bump is connected to said second bonding pad.

2. The inner layer structure of a circuit board of claim 1, further comprising a first circuit pattern on said first side of said dielectric layer forming said first bonding pad.

3. The inner layer structure of a circuit board of claim 1, further comprising a second circuit pattern on said second side of said dielectric layer forming said second bonding pad.

4. An inner layer structure of a circuit board, comprising:
a dielectric layer having a first side and a second side, wherein said dielectric layer includes a through hole penetrating through said dielectric layer and said through hole connects said first side and said second side of said dielectric layer;
a conducting plug within said through hole; and
a bump, wherein one end of said bump is connected to an end of said conducting plug near said first side.

5. The inner layer structure of a circuit board of claim 4, wherein said conducting plug includes a conducting wall on the inner side wall of said first through hole and said conducting wall extends to said first side of said dielectric layer, and a portion of said conducting wall extending to said first side of said dielectric layer forms a ring pad, wherein one end of said bump is connected to said ring pad.

6. The inner layer structure of a circuit board of claim 4, wherein said conducting plug includes a conducting column.

7. An inner layer structure of a circuit board, comprising:
a dielectric layer having a first side and a second side, wherein said dielectric layer includes a through hole penetrating through said dielectric layer and said through hole connects said first side and said second side of said dielectric layer;
a conducting plug within said through hole;
a second dielectric layer having a third side;
a bonding pad on said third side of said second dielectric layer; and
a bump, wherein one end of said bump is connected to said bonding pad and another end of said bump is connected to an end of said conducting plug near said second side of said first dielectric layer.

8. The inner layer structure of a circuit board of claim 7, further comprising a third dielectric layer filled with the space between said first dielectric layer and said second dielectric layer.

9. The inner layer structure of a circuit board of claim 7, wherein said conducting plug includes a conducting wall on the inner side wall of said first through hole and said conducting wall extends to said second side of said first dielectric layer, and a portion of said conducting wall extending to said second side of said first dielectric layer forms a ring pad, wherein another end of said bump is connected to said ring pad.

10. The inner layer structure of a circuit board of claim 7, wherein said conducting plug includes a conducting wall on the side wall of said through hole and the inner side of said conducting wall surrounds a second through hole, and one end of said bump is embedded in said second through hole and is connected to an inner side of said conducting wall near said first side of said first dielectric layer.

11. The inner layer structure of a circuit board of claim 7, wherein said conducting plug includes a conducting column.

12. The inner layer structure of a circuit board of claim 7, further comprising a circuit pattern on said third side of said second dielectric layer forming said bonding pad.

13. An inner layer structure of a circuit board, comprising: a first dielectric layer having a first side; a first bonding pad on said first side of said first dielectric layer; a first bump, wherein one end of said first bump is connected to said first bonding pad; a second dielectric layer having a second side; anda second bonding pad on said second side of said second dielectric layer, wherein said second bonding pad is connected to another end of said first bump.

14. The inner layer structure of a circuit board of claim 13, further comprising a third dielectric layer filled with the space between said first dielectric layer and said second dielectric layer.

15. The inner layer structure of a circuit board of claim 13, further comprising a second bump, wherein the one end of said second bump is connected to said second bonding pad, and said second bonding pad is indirectly connected to another end of said first bump via said second bump.

16. The inner layer structure of a circuit board of claim 13, further comprising a first circuit pattern on said first side of said first dielectric layer forming said first bonding pad.

17. The inner layer structure of a circuit board of claim 13, further comprising a second circuit pattern on said second side of said second dielectric layer forming said second bonding pad.
